(19) United States
(12) Patent Application Publication
(10) Pub. No.: US 2025/0181087 A1
(43) Pub. Date: Jun. 5, 2025

(54) TEMPERATURE CONTROL DEVICE, SUBSTRATE PROCESSING APPARATUS, AND TEMPERATURE CONTROL METHOD

(71) Applicant: Tokyo Electron Limited, Tokyo (JP)

(72) Inventor: Masaru ISAGO, Miyagi (JP)

(73) Assignee: Tokyo Electron Limited, Tokyo (JP)

(21) Appl. No.: 19/051,263

(22) Filed: Feb. 12, 2025

Related U.S. Application Data
(63) Continuation of application No. PCT/JP2023/030779, filed on Aug. 25, 2023.

(30) Foreign Application Priority Data
Sep. 1, 2022 (JP) 2022-139488

(51) Int. Cl. G05D 23/00; H01L 21/67

(52) U.S. Cl. CPC G05D 23/00; H01L 21/67248

(57) ABSTRACT

To provide a temperature control device, a substrate processing apparatus, and a temperature control method that improve accuracy and responsiveness of temperature control. The temperature control device for controlling a temperature of a temperature controller by circulating a fluid through the temperature controller, includes: a first temperature adjuster for controlling the fluid to a first temperature, a second temperature adjuster for controlling the fluid controlled to the first temperature to a second temperature, a first temperature-control flow path provided between the first temperature adjuster and the second temperature adjuster, a second temperature-control flow path provided between the second temperature adjuster and the temperature controller, and a return flow path provided between the temperature controller and the first temperature adjuster.

### CROSS-REFERENCE TO RELATED APPLICATIONS

This application is a bypass continuation application of international application No. PCT/JP2023/030779 having an international filing date of Aug. 25, 2023 and designating the United States, the international application being based upon and claiming the benefit of priority from Japanese Patent Application No. 2022-139488, filed on Sep. 1, 2022, the entire contents of each are incorporated herein by reference.

### TECHNICAL FIELD

The present disclosure relates to a temperature control device, a substrate processing apparatus, and a temperature control method.

### BACKGROUND

For example, a temperature control device is disclosed which includes a temperature controller that circulates a fluid, a heating flow path that heats the fluid and circulates the fluid to the temperature controller, a cooling flow path that cools the fluid and circulates the fluid to the temperature controller, a bypass flow path that does not pass through the heating flow path and the cooling flow path, but circulates the fluid to the temperature controller, and an adjuster that adjusts a flow ratio of the fluid that is output from the heating flow path, the cooling flow path, and the bypass flow path to the temperature controller through a junction where these flow paths join together.

### CITATION LIST

### Patent Documents

PTL 1: JP2008-276439A

### SUMMARY

In one aspect, the present disclosure provides a temperature control device, a substrate processing apparatus, and a temperature control method that improve accuracy of temperature control.

In order to solve the above-described problem, according to one or more aspects of the present application, a temperature control device for controlling a temperature of a temperature controller by circulating a fluid through the temperature controller is provided. The temperature control device includes: a first temperature adjuster configured to control the fluid to a first temperature, a temperature adjustment module including a second temperature adjuster configured to control the fluid controlled to the first temperature to a second temperature, a first temperature-control flow path provided between the first temperature adjuster and the second temperature adjuster, a second temperature-control flow path provided between the second temperature adjuster and the temperature controller, a return flow path provided between the temperature controller and the first temperature adjuster, and a tank configured to store the fluid, the tank being provided in the middle of the first temperature-control flow path between the first temperature adjuster and the temperature adjustment module.

According to one or more aspects of the present application, the temperature control device, the substrate processing apparatus, and the temperature control method that improve the accuracy of the temperature control can be provided.

### BRIEF DESCRIPTION OF DRAWINGS

FIG. 1 is an example of a configuration diagram of a plasma processing system;

FIG. 2 is an example of a configuration diagram of a plasma processing apparatus;

FIG. 3 is an example of an overall configuration diagram of a temperature control module according to one or more embodiments of the present application;

FIG. 4 is an example of an overall configuration diagram of a temperature control module according to a reference example;

FIG. 5 is a graph illustrating an example of a temperature change of a heat transfer fluid;

FIG. 6 is an example of an overall configuration diagram of a temperature control module according to one or more embodiments of the present application; and

FIG. 7 is an example of an overall configuration diagram of a temperature control module according to one or more embodiments of the present application.

### DETAILED DESCRIPTION

Hereinafter, various exemplary embodiments will be described in detail with reference to the drawings. Further, like reference numerals will be given to like or corresponding parts throughout the drawings.

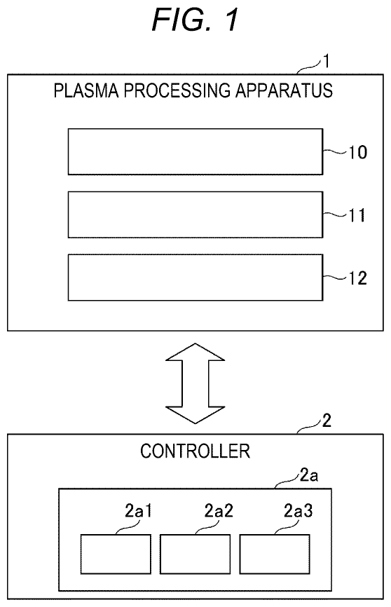

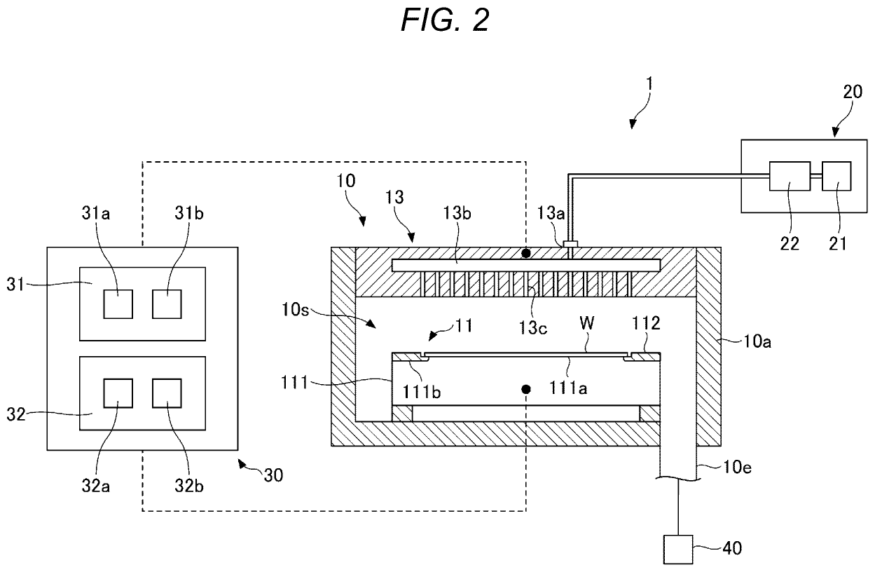

A plasma processing system (substrate processing system) will be described with reference to FIGS. 1 and 2. FIG. 1 is an example of a configuration diagram of the plasma processing system. FIG. 2 is an example of a configuration diagram of a plasma processing apparatus 1.

As illustrated in FIG. 1, in one or more embodiments of the present application, the plasma processing system includes the plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one or more embodiments of the present application, an AC signal (AC power) used by the AC plasma generator has a frequency in a range of 100 kHz to 10 GHz. Accordingly, the AC signal includes a radio frequency (RF) signal and a microwave signal. In one or more embodiments of the present application, the RF signal has a frequency in a range of 200 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein. In one or more embodiments of the present application, part or all of the controller 2 may be in the plasma processing apparatus 1. The controller 2 may include, for example, a computer 2a. For example, the computer 2a may include a processor (central processing unit (CPU)) 2a1, a storage 2a2, and a communication interface 2a3. The processor 2al may be configured to perform various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Hereinafter, a configuration example of a capacitively coupled plasma processing apparatus as an example of the plasma processing apparatus 1 will be described. As shown in FIG. 2, the capacitively coupled plasma processing apparatus 1 includes the plasma processing chamber 10, the gas supply 20, a power source 30, and the exhaust system 40. The plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one or more embodiments of the present application, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically insulated from a housing of the plasma processing chamber 10.

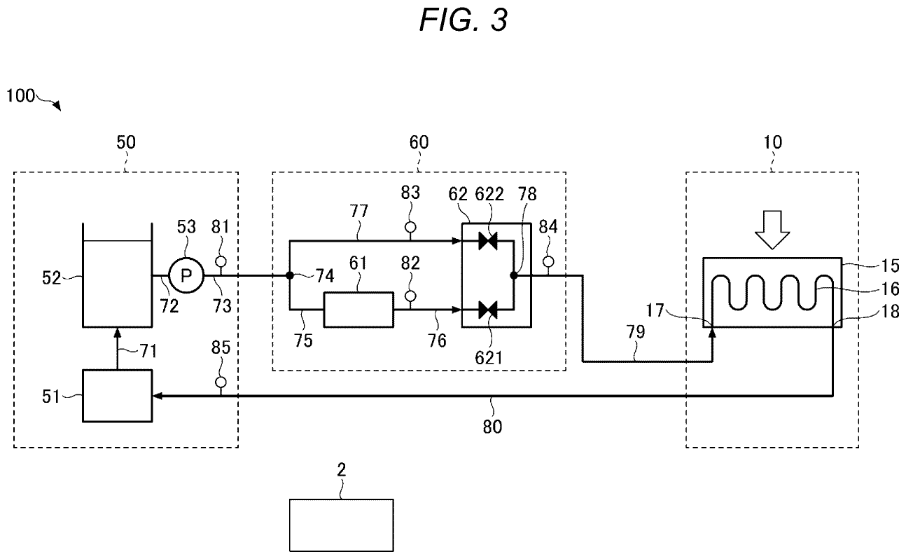

The substrate support 11 includes a main body 111 and a ring assembly 112. The main body 111 has a central region (substrate support surface) 111a for supporting a substrate (wafer) W, and an annular region (ring support surface) 111b for supporting the ring assembly 112. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. In one or more embodiments of the present application, the main body 111 includes a base and an electrostatic chuck. The base includes a conductive member. The conductive member of the base functions as a lower electrode. The electrostatic chuck is disposed on the base. An upper surface of the electrostatic chuck has a substrate support surface 111a. The ring assembly 112 includes one or more annular members. At least one of the one or more annular members is an edge ring. Although not illustrated, the substrate support 11 may include a temperature control module 100 (see FIG. 3 to be described later) configured to control at least one of the electrostatic chuck, the ring assembly 112, and the substrate W to a target temperature. The temperature control module 100 may include a heater, a heat transfer fluid, a flow path 16 (see FIG. 3 to be described later), or a combination thereof. A heat transfer fluid, such as brine or gas, flows through the flow path 16. Further, the substrate support 11 may include a heat transfer gas supply configured to supply a heat transfer gas between a rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. Further, the shower head 13 includes a conductive member. The conductive member of the shower head 13 functions as an upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one or more embodiments of the present application, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. Accordingly, the plasma is formed from at least one processing gas supplied into the plasma processing space 10s. Accordingly, the RF power source 31 may function as at least a part of the plasma generator 12. Further, supplying of the bias RF signal to the conductive member of the substrate support 11 can generate a bias potential in the substrate W to draw an ion component in the formed plasma to the substrate W.

In one or more embodiments of the present application, the RF power source 31 includes a first RF generator 31a and a second RF generator 31b. The first RF generator 31a is coupled to the conductive member of the substrate support 11 and/or the conductive member of the shower head 13 via at least one impedance matching circuit, and configured to generate a source RF signal (source RF power) for plasma generation. In one or more embodiments of the present application, the source RF signal has a frequency in the range of 13 MHz to 150 MHz. In one or more embodiments of the present application, the first RF generator 31a may be configured to generate a plurality of source RF signals having different frequencies. The generated one or a plurality of source RF signals are supplied to the conductive member of the substrate support 11 and/or the conductive member of the shower head 13. The second RF generator 31b is coupled to the conductive member of the substrate support 11 via at least one impedance matching circuit, and configured to generate a bias RF signal (bias RF power). In one or more embodiments of the present application, the bias RF signal has a lower frequency than the source RF signal. In one or more embodiments of the present application, the bias RF signal has a frequency in the range of 400 kHz to 13.56 MHz. In one or more embodiments of the present application, the second RF generator 31b may be configured to generate a plurality of bias RF signals having different frequencies. The generated one or more bias RF signals are supplied to the conductive member of the substrate support 11. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one or more embodiments of the present application, the first DC generator 32a is connected to the conductive member of the substrate support 11 and configured to generate a first DC signal. The generated first DC signal is applied to the conductive member of the substrate support 11. In one or more embodiments of the present application, the first DC signal may be applied to another electrode, such as an electrode in an electrostatic chuck. In one or more embodiments of the present application, the second DC generator 32b is connected to the conductive member of the shower head 13 and configured to generate a second DC signal. The generated second DC signal is applied to the conductive member of the shower head 13. In various embodiments, the first and second DC signals may be pulsed. The first DC generator 32a and the second DC generator 32b may be provided in addition to the RF power source 31, or the first DC generator 32a may be provided in place of the second RF generator 31b.

The exhaust system 40 may be connected, for example, to a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

Next, the temperature control module (temperature control device) 100 according to one or more embodiments of the present application will be described with reference to FIG. 3. FIG. 3 is an example of an overall configuration diagram of the temperature control module 100 according to one or more embodiments of the present application.

The temperature control module 100 includes a temperature controller 15 having the flow path 16, a chiller 50, and a temperature adjustment module 60.

The temperature control module 100 controls a temperature of the temperature controller 15 by causing a heat transfer fluid (e.g., brine) to flow through the flow path 16 formed in the temperature controller 15. In other words, the temperature control module 100 controls the temperature of the temperature controller 15 by circulating the heat transfer fluid between the flow path 16 formed in the temperature controller 15 and the chiller 50. The flow path 16 has an inlet 17 and an outlet 18. The temperature controller 15 may be, for example, the substrate support 11. In this case, the temperature control module 100 controls a temperature of at least one of the electrostatic chuck, the ring assembly 112, and the substrate W disposed in the vicinity of the substrate support 11 to a desired temperature (target temperature) by controlling a temperature of the substrate support 11 (the temperature controller 15). The temperature controller 15 is not limited to the substrate support 11, and may be, for example, an upper electrode or the sidewall 10a of the plasma processing chamber 10.

The temperature controller 15 receives heat from, for example, plasma generated in the plasma processing chamber 10 (see, e.g., a white arrow in FIG. 3). The heat transfer fluid is supplied from the inlet 17 of the flow path 16 to the temperature controller 15, and heat is exchanged between the heat transfer fluid flowing through the flow path 16 and the temperature controller 15, thereby cooling the temperature controller 15 and heating the heat transfer fluid. One end of a return flow path 80 is connected to the outlet 18 of the flow path 16. The other end of the return flow path 80 is connected to the chiller 50 (a first temperature adjuster 51 to be described later). The heat transfer fluid discharged from the outlet 18 of the flow path 16 flows into the chiller 50 through the return flow path 80.

The chiller 50 includes the first temperature adjuster 51, a tank 52, and a pump 53. The other end of the return flow path 80 is connected to one end (upstream side) of the first temperature adjuster 51. The other end (downstream side) of the first temperature adjuster 51 is connected to one end (inflow side) of the tank 52 through a flow path 71. The other end (outflow side) of the tank 52 is connected to one end (suction side) of the pump 53 through a flow path 72. The other end (discharge side) of the pump 53 is connected to one end of a flow path 73.

The first temperature adjuster 51 is, for example, a cooling device (refrigerator) that cools the heat transfer fluid, and controls a temperature of the heat transfer fluid to a first temperature. The tank 52 stores the heat transfer fluid cooled to the first temperature by the first temperature adjuster 51. The pump 53 circulates the heat transfer fluid between the flow path 16 of the temperature controller 15 and the chiller 50. The pump 53 discharges the heat transfer fluid, which is cooled to the first temperature and stored in the tank 52, to the temperature adjustment module 60 through the flow path 73.

In FIG. 3, the tank 52 is illustrated as being provided downstream of the first temperature adjuster 51 and upstream of the pump 53. However, the present disclosure is not limited thereto. The tank 52 may be provided upstream of the first temperature adjuster 51 and the pump 53. That is, the other end of the return flow path 80 may be connected to the one end (inflow side) of the tank 52, the other end (outflow side) of the tank 52 may be connected to the one end (upstream side) of the first temperature adjuster 51 through a flow path, and the other end (downstream side) of the first temperature adjuster 51 may be connected to the one end (suction side) of the pump 53 through a flow path.

As shown in FIG. 3, the tank 52 is preferably provided downstream of the first temperature adjuster 51. Accordingly, for example, even when the temperature of the heat transfer fluid discharged from the first temperature adjuster 51 fluctuates, the temperature fluctuation is absorbed by the heat transfer fluid stored in the tank 52, so that the temperature fluctuation of the heat transfer fluid discharged from the chiller 50 can be reduced.

The temperature adjustment module 60 includes a second temperature adjuster 61 and a flow ratio adjuster 62. The other end of the flow path 73 is connected to an inflow port of a branch 74. The branch 74 has one inflow port and two outflow ports. One outflow port of the branch 74 is connected to one end (upstream side) of the second temperature adjuster 61 through a flow path 75. The other end (downstream side) of the second temperature adjuster 61 is connected to one inflow port of a junction 78 through a flow path 76.

The second temperature adjuster 61 heats or cools the heat transfer fluid (the heat transfer fluid controlled to the first temperature) discharged from the chiller 50 to control the temperature of the heat transfer fluid to a second temperature. Then, the flow path 76 supplies the heat transfer fluid controlled to the second temperature to the flow path 16 of the temperature controller 15 through the junction 78 and a forward flow path 79. The second temperature adjuster 61 may be a heating device (first temperature<second temperature) that heats the heat transfer fluid, or may be a cooling device (first temperature>second temperature) that cools the heat transfer fluid. The second temperature adjuster 61 may be a device having a capacity (cooling capacity, heating capacity) smaller than that of the first temperature adjuster 51. In other words, the second temperature adjuster 61 may be a device smaller than the first temperature adjuster 51. The flow paths 71, 72, 73, and 75 provided between the first temperature adjuster 51 and the second temperature adjuster 61 are also referred to as first temperature-control flow paths. A heat transfer fluid at a first temperature flows through the first temperature-control flow path. The flow path 76 provided between the second temperature adjuster 61 and the temperature controller 15 is also referred to as a second temperature-control flow path. A heat transfer fluid at a second temperature flows through the second temperature-control flow path.

The other outflow port of the branch 74 is connected to the other inflow port of the junction 78 through a bypass flow path 77. That is, the bypass flow path 77 branches off from the first temperature-control flow path at the branch 74, and joins the second temperature-control flow path at the junction 78.

The bypass flow path 77 supplies the heat transfer fluid discharged from the chiller 50 (the heat transfer fluid controlled to the first temperature) to the flow path 16 of the temperature controller 15 through the junction 78 and the forward flow path 79, without passing through the flow path 75, the second temperature adjuster 61, and the flow path 76. A heat transfer fluid at a first temperature flows through the bypass flow path 77.

That is, the temperature adjustment module 60 forms a temperature difference between the heat transfer fluid controlled to the second temperature flowing through the flow path 76 and the heat transfer fluid controlled to the first temperature flowing through the bypass flow path 77.

The junction 78 has two inflow ports and one outflow port. The inflow ports of the junction 78 are connected to the flow path 76 and the bypass flow path 77, respectively, and these join together, and the outflow port of the junction 78 is connected to the forward flow path 79. The junction 78 is provided with the flow ratio adjuster 62. The flow ratio adjuster 62 includes a flow rate control valve 621 provided in the flow path 76 and a flow rate control valve 622 provided in the bypass flow path 77.

An opening (opening area) of each of the flow rate control valves 621 and 622 is controlled by the controller 2. Accordingly, it is possible to adjust a flow ratio (mixture ratio) between a heat transfer medium at the second temperature from the flow path 76 and a heat transfer fluid at the first temperature from the bypass flow path 77. Accordingly, it is possible to control a temperature of the heat transfer fluid circulated to the flow path 16 of the temperature controller 15.

Although the flow ratio adjuster 62 is described as including the flow rate control valves 621 and 622, the present disclosure is not limited thereto. The flow ratio adjuster 62 may have a valve (e.g., a flow rate control valve or an on-off valve) provided in at least one of the flow path 76 and the bypass flow path 77. Further, the flow ratio adjuster 62 may have a valve (e.g., a mixing valve) provided at the junction 78 of the flow path 76 and the bypass flow path 77.

The forward flow path 79 circulates the heat transfer fluid from the outflow port of the junction 78 to the inlet 17 of the flow path 16 of the temperature controller 15.

The return flow path 80 is provided between the temperature controller 15 and the chiller 50, and circulates the heat transfer fluid from the outlet 18 of the flow path 16 of the temperature controller 15 to the chiller 50.

A temperature sensor 81 that detects the temperature of the heat transfer fluid is provided in the flow path 73. A temperature sensor 82 that detects the temperature of the heat transfer fluid is provided in the flow path 76. A temperature sensor 83 that detects the temperature of the heat transfer fluid is provided in the bypass flow path 77. Either the temperature sensor 81 and the temperature sensor 83 may be used. A temperature sensor 84 that detects the temperature of the heat transfer fluid is provided downstream of the junction 78 (forward flow path 79). A temperature sensor 85 that detects the temperature of the heat transfer fluid is provided in the return flow path 80. The temperatures detected by the temperature sensors 81 to 85 are input to the controller 2.

The controller 2 controls the chiller 50. For example, the controller 2 controls an output of the first temperature adjuster (refrigerator) 51 based on the temperature of the heat transfer fluid detected by the temperature sensor 85.

The controller 2 controls the temperature adjustment module 60 such that the temperature of the heat transfer fluid supplied to the temperature controller 15 becomes a desired temperature. For example, the controller 2 controls the flow ratio adjuster 62 so that the temperature of the heat transfer fluid after joining, detected by the temperature sensor 84, becomes a predetermined temperature. The controller 2 may control the flow ratio adjuster 62 based on a temperature (first temperature) of the heat transfer fluid before the joining, detected by the temperature sensor 83 (or the temperature sensor 81), and a temperature (second temperature) of the heat transfer fluid before the joining, detected by the temperature sensor 82. That is, the controller 2 controls the temperature of the heat transfer fluid supplied to the temperature controller 15 by controlling the flow rate control valves 621 and 622 to adjust the flow ratio (mixture ratio) between the heat transfer medium at the second temperature from the flow path 76 and the heat transfer fluid at the first temperature from the bypass flow path 77. The controller 2 controls an output of the second temperature adjuster 61.

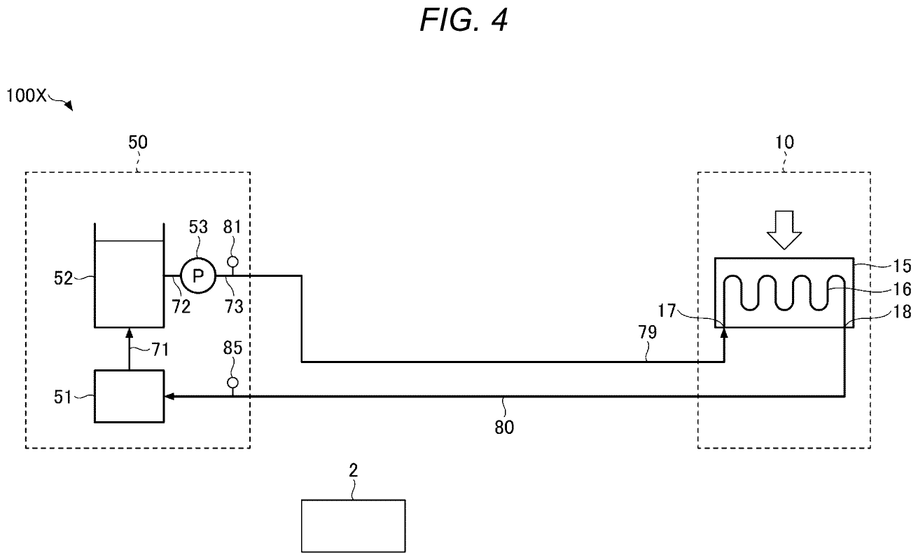

Here, a temperature control module 100X according to a reference example will be described with reference to FIG. 4. FIG. 4 is an example of an overall configuration diagram of the temperature control module 100X according to the reference example. The temperature control module 100X according to the reference example includes the temperature controller 15 having the flow path 16 and the chiller 50. That is, in the temperature control module 100X according to the reference example, the flow path 73 is connected to the forward flow path 79, and a temperature of the temperature controller 15 is controlled by circulating the heat transfer fluid between the flow path 16 formed in the temperature controller 15 and the chiller 50. Other configurations are similar to the present disclosure, and descriptions thereof will be omitted.

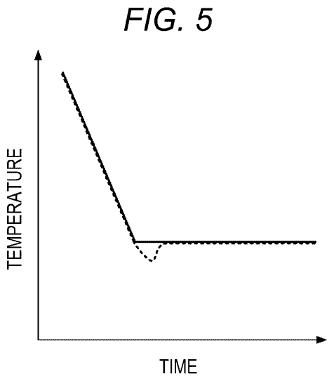

FIG. 5 is a graph illustrating an example of a temperature change of the heat transfer fluid over time. The temperature change of the heat transfer fluid in the temperature control module 100X according to the reference example is illustrated by a broken line. A temperature change of the heat transfer fluid in the temperature control module 100 according to the present embodiment is illustrated by a solid line.

Here, a case where an amount of heat input to the temperature controller 15 increases will be described by way of example. That is, the temperature of the heat transfer fluid in the return flow path 80 increases above a steady state.

In the temperature control module 100X according to the reference example, the controller 2 controls the first temperature adjuster 51 to increase a cooling capacity, thereby controlling a temperature of a heat transfer fluid supplied to the temperature controller 15. Therefore, for example, in a transient state of the temperature shown in FIG. 5, the control over the first temperature adjuster 51 does not catch up, and temperature fluctuations (overshoot, undershoot) may occur. In the example shown in FIG. 5, an undershoot occurs in the temperature control (see the broken line) of the temperature control module 100X according to the reference example.

In contrast, in the temperature control module 100 according to one or more embodiments of the present application, the controller 2 controls the first temperature adjuster 51 to increase the cooling capacity, thereby controlling the temperature of the heat transfer fluid. The controller 2 controls the output of the second temperature adjuster 61 and the flow ratio adjuster 62 (flow rate control valves 621 and 622), thereby controlling the temperature of the heat transfer fluid supplied to the temperature controller 15. Therefore, for example, in the temperature transient state shown in FIG. 5, even when the control of the first temperature adjuster 51 does not catch up and the temperature fluctuation occurs, the temperature of the heat transfer fluid can be controlled by the temperature adjustment module 60, so that the temperature fluctuation can be prevented. For example, when the temperature of the heat transfer fluid flowing through the bypass flow path 77 becomes lower than a predetermined temperature (undershoot occurs), the temperature of the heat transfer fluid supplied to the temperature controller 15 can be brought close to the predetermined temperature by mixing the heat transfer fluid flowing through the bypass flow path 77 and the heat transfer fluid flowing through the flow path 76. Accordingly, it is possible to prevent the undershoot. In the example shown in FIG. 5, the undershoot is prevented in the temperature control (see the solid line) of the temperature control module 100 according to one or more embodiments of the present application.

In a steady state, the temperature of the heat transfer fluid in the forward flow path 79 fluctuates slightly. Therefore, the temperature of the heat transfer fluid discharged from the chiller 50 may also fluctuates slightly. In contrast, in the temperature control module 100 according to one or more embodiments of the present application, the temperature adjustment module 60 can set the temperature of the heat transfer fluid supplied to the temperature controller 15 to a desired temperature. Therefore, it is possible to improve accuracy of temperature control of the heat transfer fluid supplied to the temperature controller 15.

As compared with temperature control of the heat transfer fluid by the first temperature adjuster 51, temperature control of the heat transfer fluid by the temperature adjustment module 60 can have a faster response. Accordingly, it is possible to quickly prevent temperature fluctuations (overshoot, undershoot).

The second temperature adjuster 61 can be a device that is smaller in size and has a lower output than the first temperature adjuster 51. Accordingly, it is possible to prevent the temperature control module 100 from becoming large. For example, a temperature difference formed in the second temperature adjuster 61 (a temperature difference between a temperature of the temperature sensor 83 and a temperature of the temperature sensor 82) may be smaller than a temperature difference formed in the first temperature adjuster 51 (a temperature difference between a temperature of the temperature sensor 85 and a temperature of the temperature sensor 81). A flow rate of the heat transfer fluid flowing through the second temperature adjuster 61 may be smaller than a flow rate of the heat transfer fluid flowing through the first temperature adjuster 51. A product of the temperature difference and the flow rate in the second temperature adjuster 61 may be smaller than a product of the temperature difference and the flow rate in the first temperature adjuster 51.

In FIG. 3, a case where the first temperature adjuster 51 is a cooling device and the second temperature adjuster 61 is a heating device is described as an example. However, the present disclosure is not limited thereto. The first temperature adjuster 51 may be a cooling device, and the second temperature adjuster 61 may be a cooling device. Accordingly, for example, it is possible to prevent an overshoot of the temperature of the heat transfer fluid. Further, the second temperature adjuster 61 may be configured to selectively heat and cool the heat transfer fluid.

In FIG. 3, a case where the temperature controller 15 is cooled by circulating a heat transfer fluid is described as an example. However, the present disclosure is not limited thereto. The temperature controller 15 may be heated by circulating a heat transfer fluid. In this case, the first temperature adjuster 51 may be a heating device. The second temperature adjuster 61 may be a cooling device or a heating device. Accordingly, it is possible to prevent temperature fluctuations of the heat transfer fluid supplied to the temperature controller 15.

Although the temperature adjustment module 60 is described as including the flow path 76 having the second temperature adjuster 61, the bypass flow path 77, and the flow ratio adjuster 62, the present disclosure is not limited thereto.

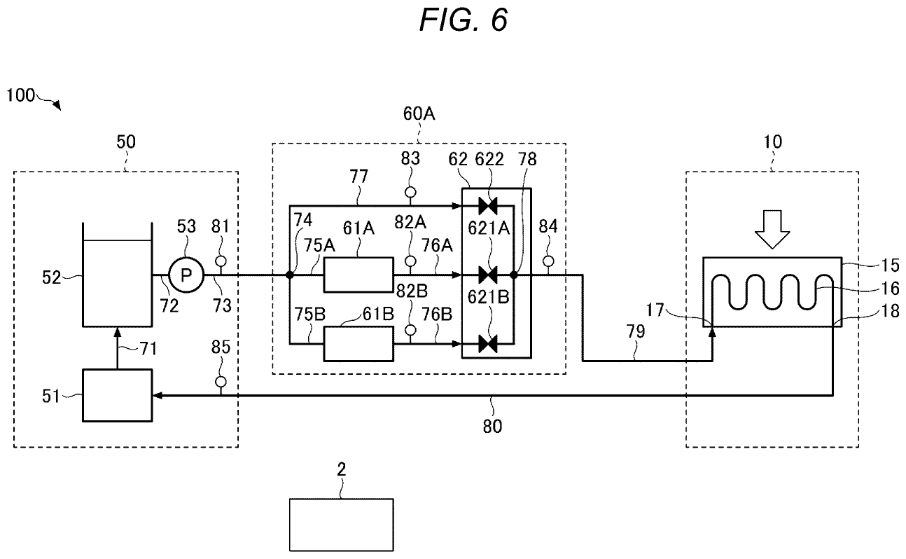

The temperature control module 100 according to one or more embodiments of the present application will be further described with reference to FIG. 6. FIG. 6 is an example of an overall configuration diagram of the temperature control module 100 according to one or more embodiments of the present application.

The temperature control module 100 includes the temperature controller 15 having the flow path 16, the chiller 50, and a temperature adjustment module 60A. Similar to the chiller 50 (see FIG. 3) of the temperature control module 100 according to one or more embodiments of the present application, the chiller 50 includes the first temperature adjuster 51, the tank 52, and the pump 53.

The temperature adjustment module 60A includes a second temperature adjuster 61A, a third temperature adjuster 61B, and the flow ratio adjuster 62. The other end of the flow path 73 is connected to the inflow port of the branch 74. The branch 74 has one inflow port and three outflow ports. A first outflow port of the branch 74 is connected to one end (upstream side) of the second temperature adjuster 61A through a flow path 75A. The other end (downstream side) of the second temperature adjuster 61A is connected to a first inflow port of the junction 78 through a flow path 76A. A second outflow port of the branch 74 is connected to one end (upstream side) of the third temperature adjuster 61B through a flow path 75B. The other end (downstream side) of the third temperature adjuster 61B is connected to a second inflow port of the junction 78 through a flow path 76B.

The second temperature adjuster 61A heats the heat transfer fluid (the heat transfer fluid controlled to the first temperature) discharged from the chiller 50, and controls the temperature of the heat transfer fluid to the second temperature (first temperature<second temperature). Then, the flow path 76A supplies the heat transfer fluid controlled to the second temperature to the flow path 16 of the temperature controller 15 through the junction 78 and the forward flow path 79.

The third temperature adjuster 61B cools the heat transfer fluid (the heat transfer fluid controlled to the first temperature) discharged from the chiller 50, and controls the temperature of the heat transfer fluid to a third temperature (first temperature>third temperature). Then, the flow path 76B supplies the heat transfer fluid controlled to the third temperature to the flow path 16 of the temperature controller 15 through the junction 78 and the forward flow path 79.

The second temperature adjuster 61A and the third temperature adjuster 61B may be devices having a capacity (cooling capacity, heating capacity) smaller than that of the first temperature adjuster 51. In other words, the second temperature adjuster 61A and the third temperature adjuster 61B may be devices smaller than the first temperature adjuster 51. The flow paths 71, 72, 73, 75A, and 75B provided between the first temperature adjuster 51 and the second temperature adjuster 61A and the third temperature adjuster 61B are also referred to as the first temperature-control flow paths. A heat transfer fluid at the first temperature flows through the first temperature-control flow path. The flow path 76A provided between the second temperature adjuster 61A and the temperature controller 15 is also referred to as the second temperature-control flow path. A heat transfer fluid at a second temperature flows through the second temperature-control flow path. The flow path 76B provided between the third temperature adjuster 61B and the temperature controller 15 is also referred to as a third temperature-control flow path. A heat transfer fluid at the third temperature flows through the third temperature-control flow path.

A third outflow port of the branch 74 is connected to a third inflow port of the junction 78 through the bypass flow path 77. That is, the bypass flow path 77 branches off from the first temperature-control flow path at the branch 74, and joins the second temperature-control flow path and the third temperature-control flow path at the junction 78.

The bypass flow path 77 supplies the heat transfer fluid discharged from the chiller 50 (the heat transfer fluid controlled to the first temperature) to the flow path 16 of the temperature controller 15 through the junction 78 and the forward flow path 79, without passing through the flow path 75A, the second temperature adjuster 61A, and the flow path 76A, and without passing through the flow path 75B, the third temperature adjuster 61B, and the flow path 76B. A heat transfer fluid at the first temperature flows through the bypass flow path 77. That is, the temperature adjustment module 60A forms a temperature difference between the heat transfer fluid controlled to the second temperature and flowing through the flow path 76A, the heat transfer fluid controlled to the third temperature and flowing through the flow path 76B, and the heat transfer fluid controlled to the first temperature and flowing through the bypass flow path 77.

The junction 78 has three inflow ports and one outflow port. The inflow ports of the junction 78 are connected to the flow path 76A, the flow path 76B, and the bypass flow path 77, respectively, and these join together, and the outflow port of the junction 78 is connected to the forward flow path 79. The junction 78 is provided with the flow ratio adjuster 62. The flow ratio adjuster 62 includes a flow rate control valve 621A provided in the flow path 76A, a flow rate control valve 621B provided in the flow path 76B, and the flow rate control valve 622 provided in the bypass flow path 77.

An opening (opening area) of each of the flow rate control valves 621A, 621B, and 622 is controlled by the controller 2. Accordingly, it is possible to adjust a flow ratio (e.g., mixture ratio) of a heat transfer medium at the second temperature from the flow path 76A, a heat transfer medium at the third temperature from the flow path 76B, and a heat transfer fluid at the first temperature from the bypass flow path 77. Accordingly, it is possible to control a temperature of the heat transfer fluid circulated to the flow path 16 of the temperature controller 15.

Although the flow ratio adjuster 62 is described as including the flow rate control valves 621A, 621B, and 622, the present disclosure is not limited thereto. The flow ratio adjuster 62 may have a valve (e.g., a flow rate control valve or an on-off valve) provided in at least one of the flow paths 76A and 76B and the bypass flow path 77. Further, the flow ratio adjuster 62 may have a valve (e.g., a mixing valve) provided at the junction 78 of the flow paths 76A and 76B and the bypass flow path 77.

A temperature sensor 82A that detects the temperature of the heat transfer fluid is provided in the flow path 76A. A temperature sensor 82B that detects the temperature of the heat transfer fluid is provided in the flow path 76B. The temperature sensor 83 that detects the temperature of the heat transfer fluid is provided in the bypass flow path 77. The temperature sensor 84 that detects the temperature of the heat transfer fluid is provided downstream of the junction 78 (forward flow path 79).

According to the temperature control module 100 in one or more embodiments of the present application, it is possible to prevent temperature fluctuations (e.g., overshoot/excess temperature or undershoot/insufficient temperature) of the heat transfer fluid supplied to the temperature controller 15. For example, when the temperature of the heat transfer fluid flowing through the bypass flow path 77 becomes lower than a predetermined temperature (i.e., undershoot occurs), the temperature of the heat transfer fluid supplied to the temperature controller 15 can be brought close to the predetermined temperature by mixing the heat transfer fluid flowing through the bypass flow path 77 and the heat transfer fluid flowing through the flow path 76A. For example, when the temperature of the heat transfer fluid flowing through the bypass flow path 77 becomes higher than a predetermined temperature (i.e., overshoot occurs), the temperature of the heat transfer fluid supplied to the temperature controller 15 can be brought close to the predetermined temperature by mixing the heat transfer fluid flowing through the bypass flow path 77 and the heat transfer fluid flowing through the third temperature-control flow path 76B. Therefore, it is possible to improve accuracy and precision of temperature control of the heat transfer fluid supplied to the temperature controller 15.

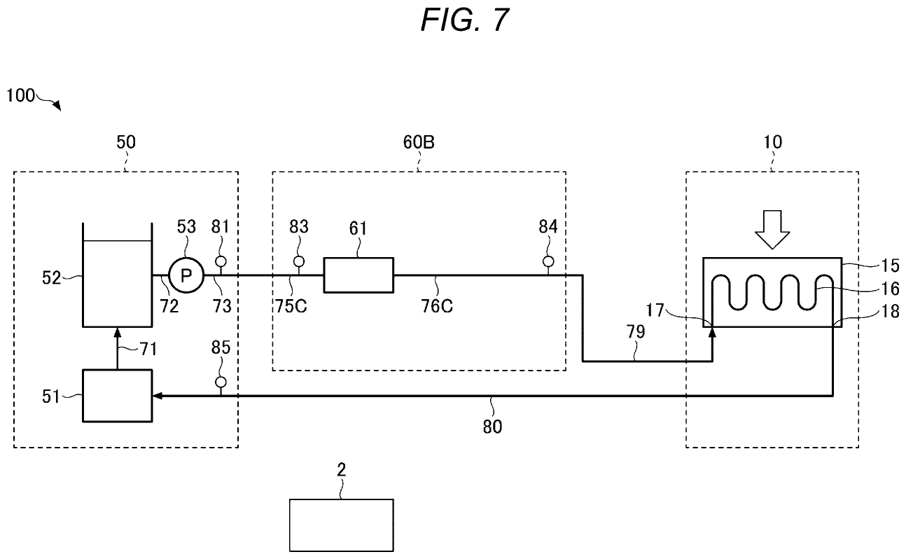

The temperature control module 100 according to one or more embodiments of the present application will be further described with reference to FIG. 7. FIG. 7 is an example of an overall configuration diagram of the temperature control module 100 according to one or more embodiments of the present application.

The temperature control module 100 includes the flow path 16 of the temperature controller 15, the chiller 50, and a temperature adjustment module 60B. Similar to the chiller 50 (see FIG. 3) of the temperature control module 100 according to one or more embodiments of the present application, the chiller 50 includes the first temperature adjuster 51, the tank 52, and the pump 53.

The temperature adjustment module 60B includes the second temperature adjuster 61. The other end of the flow path 73 is connected to the one end (upstream side) of the second temperature adjuster 61 through a flow path 75C. The other end (downstream side) of the second temperature adjuster 61 is connected to the forward flow path 79 through a flow path 76C. The flow paths 71, 72, 73, and 75C provided between the first temperature adjuster 51 and the second temperature adjuster 61 are also referred to as the first temperature-control flow paths. A heat transfer fluid at a first temperature flows through the first temperature-control flow path. The flow path 76C provided between the second temperature adjuster 61 and the temperature controller 15 is also referred to as the second temperature-control flow path. A heat transfer fluid at the second temperature flows through the second temperature-control flow path.

According to the temperature control module 100 in one or more embodiments of the present application, even when the temperature of the heat transfer fluid discharged from the chiller 50 fluctuates, the temperature may be controlled by the second temperature adjuster 61, and it supplied to the temperature controller 15. Therefore, it is possible to improve accuracy of temperature control of the heat transfer fluid supplied to the temperature controller 15.

The embodiments disclosed above include, for example, the following aspects.

### APPENDIX 1

A temperature control device for controlling a temperature of a temperature controller by circulating a fluid through the temperature controller, the temperature control device including:
a first temperature adjuster configured to control the fluid to a first temperature,
a second temperature adjuster configured to control the fluid controlled to the first temperature to a second temperature,
a first temperature-control flow path provided between the first temperature adjuster and the second temperature adjuster,
a second temperature-control flow path provided between the second temperature adjuster and the temperature controller, and
a return flow path provided between the temperature controller and the first temperature adjuster.

### APPENDIX 2

The temperature control device according to Appendix 1, further including:
a bypass flow path provided between the first temperature adjuster and the temperature controller and configured to supply the fluid controlled to the first temperature to the temperature controller without passing through the second temperature adjuster,
a flow ratio adjuster configured to adjust a flow ratio between the fluid supplied from the second temperature-control flow path to the temperature controller and the fluid supplied from the bypass flow path to the temperature controller, and
a controller configured to control the flow ratio adjuster.

### APPENDIX 3

The temperature control device according to Appendix 2, further including:
a junction where the second temperature-control flow path and the bypass flow path join together, and
a temperature detector provided in the junction and configured to detect a temperature of the fluid, in which
the controller adjusts the flow ratio of the flow ratio adjuster based on the temperature of the fluid detected by the temperature detector.

### APPENDIX 4

The temperature control device according to Appendix 2 or 3, in which
the flow ratio adjuster includes a valve provided in at least one of the second temperature-control flow path and the bypass flow path, and
the controller adjusts the flow ratio of the fluid by controlling the valve.

### APPENDIX 5

The temperature control device according to any one of Appendixes 1 to 4, in which
the first temperature adjuster is a cooling device configured to cool the fluid, and
the second temperature adjuster is a heating device configured to heat the fluid.

### APPENDIX 6

The temperature control device according to any one of Appendixes 1 to 4, in which
the first temperature adjuster is a heating device configured to heat the fluid, and
the second temperature adjuster is a cooling device configured to cool the fluid.

### APPENDIX 7

The temperature control device according to any one of Appendixes 1 to 4, in which
the first temperature adjuster and the second temperature adjuster are cooling devices configured to cool the fluid, and
the second temperature is lower than the first temperature.

### APPENDIX 8

The temperature control device according to any one of Appendixes 1 to 4, in which
the first temperature adjuster and the second temperature adjuster are heating devices configured to heat the fluid, and
the second temperature is higher than the first temperature.

### APPENDIX 9

The temperature control device according to any one of Appendixes 1 to 8, further including:
a tank that stores the fluid between the first temperature adjuster and the second temperature adjuster.

### APPENDIX 10

The temperature control device according to any one of Appendixes 1 to 8, further including:
a tank that stores the fluid between the temperature controller and the first temperature adjuster.

### APPENDIX 11

A substrate processing apparatus including:
the temperature control device according to any one of Appendixes 1 to 10.

### APPENDIX 12

The substrate processing apparatus according to Appendix 11, in which the temperature controller is a stage on which a substrate is placed.

### APPENDIX 13

A temperature control method for a temperature control device to control a temperature of a temperature controller by circulating a fluid through the temperature controller, the temperature control device including a first temperature adjuster configured to control the fluid to a first temperature, a second temperature adjuster configured to control the fluid controlled to the first temperature to a second temperature, a first temperature-control flow path provided between the first temperature adjuster and the second temperature adjuster, a second temperature-control flow path provided between the second temperature adjuster and the temperature controller, a bypass flow path provided between the first temperature adjuster and the temperature controller and configured to supply the fluid controlled to the first temperature to the temperature controller without passing through the second temperature-control flow path, a return flow path provided between the temperature controller and the first temperature adjuster, and a flow ratio adjuster configured to adjust a flow ratio between the fluid supplied from the second temperature-control flow path to the temperature controller and the fluid supplied from the bypass flow path to the temperature controller,
the temperature control method including:
controlling the flow ratio to control a temperature of the fluid flowing through the temperature controller.

The present invention is not limited to the configurations described in connection with the embodiments that have been described heretofore, or to the combinations of these configurations with other elements. Various variations and modifications may be made without departing from the scope of the present invention, and may be adopted according to applications.

1. A temperature control device for controlling a temperature of a temperature controller by circulating a fluid through the temperature controller, the temperature control device comprising:
a first temperature adjuster configured to control the fluid to a first temperature,
a temperature adjustment module including a second temperature adjuster configured to control the fluid controlled to the first temperature to a second temperature,
a first temperature-control flow path provided between the first temperature adjuster and the second temperature adjuster,
a second temperature-control flow path provided between the second temperature adjuster and the temperature controller,
a return flow path provided between the temperature controller and the first temperature adjuster, and
a tank configured to store the fluid, the tank being provided in the middle of the first temperature-control flow path between the first temperature adjuster and the temperature adjustment module.

2. The temperature control device according to claim 1, wherein
the temperature adjustment module further includes:
a bypass flow path provided between the first temperature adjuster and the temperature controller and configured to supply the fluid controlled to the first temperature to the temperature controller without passing through the second temperature adjuster,
a flow ratio adjuster configured to adjust a flow ratio between the fluid supplied from the second temperature-control flow path to the temperature controller and the fluid supplied from the bypass flow path to the temperature controller, and
circuitry configured to control the flow ratio adjuster.

3. The temperature control device according to claim 2, wherein
the temperature adjustment module further includes:
a junction where the second temperature-control flow path and the bypass flow path join together; and
a temperature detector provided in the junction and configured to detect a temperature of the fluid, and
the circuitry adjusts the flow ratio of the flow ratio adjuster based on the temperature of the fluid detected by the temperature detector.

4. The temperature control device according to claim 2, wherein
the flow ratio adjuster includes a valve provided in at least one of the second temperature-control flow path and the bypass flow path, and
the circuitry adjusts the flow ratio of the fluid by controlling the valve.

5. The temperature control device according to claim 1, wherein
the first temperature adjuster is a cooling device configured to cool the fluid, and
the second temperature adjuster is a heating device configured to heat the fluid.

6. The temperature control device according to claim 1, wherein
the first temperature adjuster is a heating device configured to heat the fluid, and
the second temperature adjuster is a cooling device configured to cool the fluid.

7. The temperature control device according to claim 1, wherein
the first temperature adjuster and the second temperature adjuster are cooling devices configured to cool the fluid, and
the second temperature is lower than the first temperature.

8. The temperature control device according to claim 1 wherein
the first temperature adjuster and the second temperature adjuster are heating devices configured to heat the fluid, and
the second temperature is higher than the first temperature.

9. A substrate processing apparatus comprising:
the temperature control device according to claim 1; and
a substrate support; and
a gas introduction unit including a shower head.

10. The substrate processing apparatus according to claim 9, wherein
the temperature control device is a stage on which a substrate is placed.

11. A temperature control method for a temperature control device to control a temperature of a temperature controller by circulating a fluid through the temperature controller, the temperature control device including:
a first temperature adjuster configured to control the fluid to a first temperature;
a temperature adjustment module including a second temperature adjuster configured to control the fluid controlled to the first temperature to a second temperature;
a first temperature-control flow path provided between the first temperature adjuster and the second temperature adjuster;
a second temperature-control flow path provided between the second temperature adjuster and the temperature controller;
a bypass flow path provided between the first temperature adjuster and the temperature controller and configured to supply the fluid controlled to the first temperature to the temperature controller without passing through the second temperature-control flow path;
a return flow path provided between the temperature controller and the first temperature adjuster;
a tank configured to store the fluid, the tank being provided in the middle of the first temperature-control flow path between the first temperature adjuster and the temperature adjustment module; and
a flow ratio adjuster configured to adjust a flow ratio between the fluid supplied from the second temperature-control flow path to the temperature controller and the fluid supplied from the bypass flow path to the temperature controller,
the temperature control method comprising:
controlling the flow ratio adjuster to adjust the flow ratio to control a temperature of the fluid flowing through the temperature controller.

12. The temperature control method according to claim 11, wherein
the temperature adjustment module further includes:
a junction where the second temperature-control flow path and the bypass flow path join together, and
a temperature detector provided in the junction and configured to detect a temperature of the fluid, and
the method further comprises adjusting the flow ratio based on the temperature of the fluid detected by the temperature detector.

13. The temperature control method according to claim 11, wherein
the flow ratio adjuster includes a valve provided in at least one of the second temperature-control flow path and the bypass flow path, and
the method further comprises adjusting the flow ratio by controlling the valve.

14. The temperature control method according to claim 11, wherein:
the first temperature adjuster is a cooling device, and
the second temperature adjuster is a heating device.

15. The temperature control method according to claim 11, wherein
the first temperature adjuster is a heating device, and
the second temperature adjuster is a cooling device.

16. The temperature control method according to claim 11, wherein
the first temperature adjuster and the second temperature adjuster are cooling devices, and
the second temperature is lower than the first temperature.

17. The temperature control method according to claim 11, wherein
the first temperature adjuster and the second temperature adjuster are heating devices, and
the second temperature is higher than the first temperature.

18. The temperature control method according to claim 11, wherein
the temperature controller is a substrate support disposed in a plasma processing chamber.

19. A temperature control method comprising:
circulating a fluid through a temperature controller disposed in a plasma processing chamber;
controlling, by a first temperature adjuster, the fluid to a first temperature after the fluid has passed through the temperature controller;
storing the fluid controlled to the first temperature in a tank; then
pumping, via a pump, the fluid from the tank to a temperature adjustment module, the temperature adjustment module including:
a second temperature adjuster in a first flow path; and
a bypass flow path; and
controlling, by the second temperature adjuster, to heat the fluid to a second temperature, the second temperature being higher than the first temperature, wherein
the tank is provided between the first temperature adjuster and the temperature adjustment module.

20. The temperature control method according to claim 19, wherein
the temperature adjustment module further includes a flow ratio adjuster including a first flow rate control valve in the first flow path and a second flow rate control valve in the bypass flow path, and
the method further comprises controlling the first flow rate control valve and the second flow rate control valve to adjust a flow in the first flow path and the second flow path to adjust the temperature of the fluid.
